(19) United States
(12) Patent Application Publication
(10) Pub. No.: US 2007/0210433 A1
(43) Pub. Date: Sep. 13, 2007

(54) Integrated device having a plurality of chip arrangements and method for producing the same

(76) Inventors: Rajesh Subraya, Munich (DE); Helmut Fischer, Neubiberg (DE); Ingo Wennemuth, Munich (DE); Minka Gospodinova, Munich (DE); Jochen Thomas, Munich (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/371,204

(22) Filed: Mar. 8, 2006

(51) Int. Cl. H01L 23/02; H01L 21/00

(52) U.S. Cl. 257/686; 438/109; 257/778; 438/108; 257/E23.085

(57) ABSTRACT

The invention provides an integrated device comprising a plurality of non-individually-encapsulated chip arrangements, each of which having a plurality of contact elements for contacting a contact pad, wherein the plurality of chip arrangements are stacked on each other such that the respective contact elements provide electrical connections to the respective chip arrangement, and a common integral mold arranged to encapsulate the plurality of stacked chip arrangements.

### CROSS-REFERENCE TO RELATED APPLICATIONS

This application is related to U.S. patent application Ser. No. 11/039,293, Attorney Docket No. INFN/0097 (2004P53356US), entitled SIGNAL REDISTRIBUTION USING BRIDGE LAYER FOR MULTICHIP MODULE, filed Jan. 20, 2005, by Thoai That Le et al., U.S. patent application Ser. No. 11/208,362, Attorney Docket No. INFN/0140, entitled METHOD FOR MCP PACKAGING FOR BALANCED PERFORMANCE, filed Aug. 19, 2005, by Farid Barakat et al., and U.S. patent application Ser. No. 11/079,620, Attorney Docket No. INFN/WB0157, entitled METHOD FOR PRODUCING CHIP STACKS AND CHIP STACKS FORMED BY INTEGRATED DEVICES, filed Mar. 14, 2005, by Harald Gross. Each of the aforementioned related patent applications is herein incorporated by reference in its entirety.

### BACKGROUND OF THE INVENTION

1. Field of the Invention

The present invention is related to an integrated device having a plurality of chip arrangements, each of which being provided with one or more contact elements for contacting a contact pad. The present invention is further related to a method for producing such an integrated device.

2. Description of the Related Art

To increase the performance of electronic devices in terms of signal transmission and integration, modern devices may comprise a plurality of chips integrated in a single package or a plurality of chips wherein each chip is packaged and wherein the packages are stacked to provide a compact electronic device.

According to the first proposal above, a stacking of bare dies requires each of the dies to be tested before being stacked and packaged, which is technically expensive and time-consuming and causes high costs. Regarding the second proposal above, the stacking of packaged devices wherein each packaged device is separately encapsulated with a mold to protect the die therein from the environment, however, has an issue in that the encapsulation of each die increases their heights such that the overall height of the electronic device becomes undesirably high.

### SUMMARY OF THE INVENTION

Therefore, one embodiment of the present invention provides an integrated device having a plurality of chip arrangements which can be manufactured with reduced costs and provide a high integration.

A further embodiment of the present invention provides an integrated device having a plurality of chip arrangements wherein each chip arrangement can be functionally tested before assembled to the integrated device in a facilitated manner.

Another embodiment of the present invention provides an integrated device having a plurality of chip arrangements wherein the integrated device has a reduced height compared to package stack as known conventionally.

A further embodiment of the present invention provides a method for producing an integrated device having a plurality of chips with a high yield and in a cost-efficient manner, wherein the height of the produced integrated device is reduced compared to a conventional package stack.

According to a first aspect of the present invention, an integrated device is provided which includes a plurality of non-encapsulated chip arrangements each of which having a plurality of contact elements for contacting a contact pad, wherein the chip arrangements are stacked on each other such that the respective contact elements provide electrical connections to the respective chip arrangements, and a common integral mold arranged to encapsulate the stacked chip arrangements.

In the present invention, a chip arrangement is defined as a chip which is provided with a plurality of contact elements for providing external contacts to the chip by placing the contact elements on respective contact pads. In one embodiment, the contact pads are formed as solder bumps, e.g., solder balls, which may be soldered to the respective contact pads. The chip arrangement is non-encapsulated so that the height of the chip arrangement is not unnecessarily increased. On the other hand, the contact element allows for carrying out a functional test of the chip in a facilitated and cost-effective manner prior to the stacking. To protect the chip arrangements from the environmental influences, a common integral mold is arranged around the chip arrangements to encapsulate them.

Each of the plurality of chip arrangements may comprise one of a flip chip on which the plurality of contact elements are directly arranged, and a BGA (i.e., Ball Grid Array) arrangement wherein a chip is arranged on a first surface of a substrate. On a second opposing surface of the substrate, the plurality of contact elements is provided which has an electrical connection with integrated circuits included in the chip.

According to a further embodiment of the present invention, the plurality of chip arrangements comprises at least one BGA arrangement and at least one flip chip. A package substrate may be provided on which the at least one BGA arrangement and the at least one flip chip are arranged. The flip chip may be arranged on the package-substrate so that its contact elements contact associated contact pads of the package-substrate and wherein the BGA arrangement is arranged on the package substrate so that its contact elements contact respective further contact pads of the package substrate, wherein the plurality of contact elements of the BGA arrangements are located so that an area is formed on which no contact elements are provided, wherein the BGA arrangement is stacked onto the flip chip so that the area covers the flip chip.

According to an embodiment of the present invention, the common mold is arranged on the package substrate so that only one side of the package substrate is covered with the common mold. Thereby, an opposing side of the package substrate can be used for providing electrical interconnections to the stacked chip arrangements contained in the integrated device.

According to a further aspect of the present invention, a method for producing an integrated device including a plurality of chip arrangements is provided. The chip arrangements each have contact elements for contacting respective contact pads. The method comprises the steps of stacking the plurality of chip arrangements and encapsulating the plurality of chip arrangements so that a plurality of contact elements of at least one of the chip arrangements is externally contactable and therefore not covered by the encapsulation.

In one embodiment, at least one of the chip arrangements may be provided as a flip chip on which the plurality of contact elements are directly arranged, and at least one of the chip arrangements may be provided as a BGA arrangement, wherein a chip is arranged on a first surface of a substrate, wherein on a second opposing surface of the substrate, a plurality of contact elements is provided which are in electrical connection with the chip. Both, the flip chip and the BGA arrangement can be placed on a package substrate so that the respective contact elements of the flip chip contact associated contact pads of the package substrate and wherein the BGA arrangement is arranged on the package substrate so that its respective contact elements contact respective further contact pads of the package substrate, wherein the plurality of contact elements of the BGA arrangement are arranged so that an area is formed on which no contact elements are provided, and wherein the BGA arrangement is stacked onto the flip chip so that the area covers the flip chip.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows an integrated device according to a first embodiment;

FIG. 2 shows an integrated device according to a second embodiment;

FIG. 3 shows an integrated device according to a third embodiment; and

FIG. 4 shows an integrated device according to a fourth embodiment.

### DETAILED DESCRIPTION OF THE PREFERRED EMBODIMENT

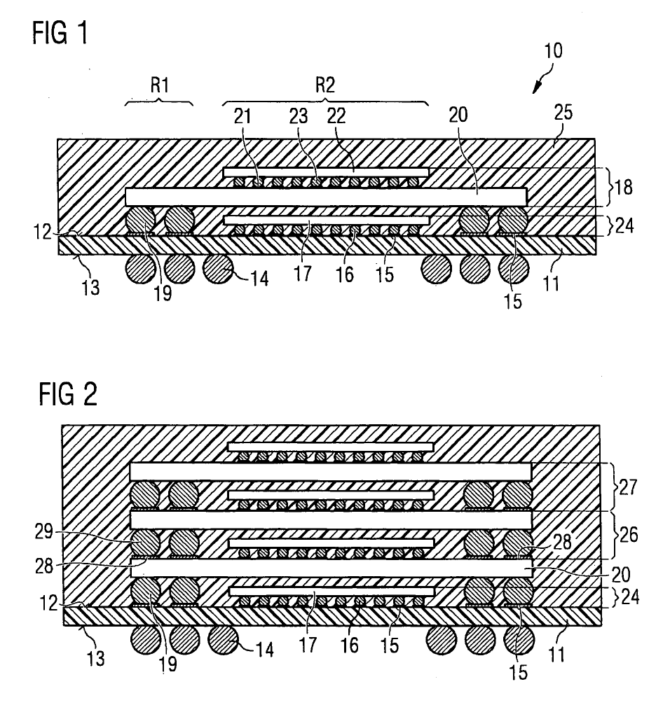

In FIG. 1 an integrated device 10 according to the present invention is shown. The integrated device 10 comprises a package substrate 11 on a first surface 12 of which a plurality of chip arrangements are placed. On a second surface 13 of the package substrate 11, contact elements 14 in the form of, e.g., solder balls and the like are arranged. The first surface 12 of the package substrate 11 is provided with first contact pads 15. The chip arrangements are placed on the package substrate 11 in a stacked manner. The chip arrangements comprise a flip chip device 17 which is provided with second contact elements 16 which are in contact with a part of the first contact pads 15 of the package substrate 11 associated thereto. A second chip arrangement 18 is formed as a BGA chip arrangement which comprises third contact elements 19, e.g., formed as solder balls and the like on a substrate 20. The substrate 20 comprises further contact pads 21 on a surface opposing the surface on which the contact elements 19 are provided and which are for contacting with fourth contact elements 23 of a second flip chip 22 to provide an electrical connection.

The first contact pads 15 of the package substrate 11 and the first contact elements 14 are interconnected according to a pre-determined scheme such that one or more of the first contact elements 14 is connected with one or more of the first contact pads 15, respectively, by means of a (not shown) redistribution layer included within the package substrate 11. The chip arrangement 18 also has a redistribution layer include in the substrate 20 which provides an electrical interconnection between the third contact elements 19 and the second contact pads 21 on the BGA substrate 20.

The first and the second chip arrangements 24, 18 are placed on the package substrate 11 such that the chips 17 and 22 are substantially arranged in a stacked condition, i.e., arranged in parallel with regard to the first surface of the package substrate 11 on top of each other. The third contact elements 19 of the second chip arrangement 18 are located in an outer region R1 of the substrate 20 such that an area is enclosed in an inner region R2 of the substrate 20. Thereby, the second chip arrangement 18 can be placed on top of the first chip arrangement 24 so that the first contact elements 19 are placed outside of the first chip arrangement 24 which is formed as a flip chip. The inner region R2 of the substrate 20 therefore is located on top of the first chip arrangement 24 with regard to the package substrate 11.

It is shown in FIG. 1 as one embodiment of the present invention that flip chips are used to provide chip arrangements so that a bond-wire connection for an electrical contacting can be avoided. In further embodiments, however, it is contemplated that at least one of the chip arrangements 24, 18 uses a bond wire to provide an electrical interconnection between the respective chip and the respective contact elements.

The term chip arrangement as used herein defines an arrangement of one chip and a plurality of contact elements, wherein the contact elements are made to be externally contacted and to provide a direct or indirect electrical connection to the chip on which, e.g., electrically operable structures may be employed. A chip arrangement may be a flip chip having contact elements directly attached to pads on the chip. A chip arrangement may further be a BGA arrangement wherein a substrate having contact elements is provided wherein the contact elements are in electrical connection with a chip arranged on the substrate, wherein the chip is formed as a flip chip or any other chip which is connected to the substrate by means of bond wires and the like. Different kind of chip arrangements can be used at a time to provide the stacked device as long as the chip arrangements are not encapsulated by a mold or a similar encapsulation material prior to their stacking.

After the chip arrangements 24, 18 are stacked onto each other, a common integral mold 25 is applied in a single step such that the liquid mold flows into the spacing between the chip arrangements to provide a secure protection against environmental influences and to avoid having any air filled cavity formed within the integrated device 10. Usually, a common mold can be used for the encapsulation process as long as the mold has a viscosity which is low enough that it can easily flow between the chip arrangements.

As shown in the first embodiment of the present invention, the mold 25 is applied on the first surface 12 of the package substrate 11 such that the second surface 13 of the package substrate 11 is not covered with the mold 25 so that the first contact element 14 can be externally connected to apply electrical signals to each of the chips in the integrated device 10.

In FIG. 2, a second embodiment of the present invention is shown. Same reference signs indicate elements with the same or similar functionality. The embodiment of FIG. 2 differs from the embodiment of FIG. 1 in that on the second chip arrangement 18, two further, i.e., a third and a fourth, (although other numbers of further chip arrangement are also contemplated) chip arrangements 26, 27 in the form of BGA arrangements are stacked. To provide an electrical connection, third contact pads 28 are provided on the substrate 20 of the second chip arrangement 18 so that the third chip arrangement 26 stacked thereon can be placed so that its fifth contact elements 29 are associated to the third contact pads 28 on the substrate 20. In a similar manner, each of the further chip arrangements can be stacked wherein its respective contact elements contact respective contact pads of one of the respective chip arrangements which is located below with regard to the package substrate 11.

As already explained with regard to FIG. 1, while stacking, the chip arrangements are all non-encapsulated. After all chip arrangements are stacked, a common integral mold can be applied so that the chip stack as a whole is encapsulated to protect the chips from environmental influences. The chip arrangements 18, 26, 27 which use a substrate such as the substrate 20 for providing the electrical connection between the chip and the respective contact elements can have a plurality of designs. The chip of the respective chip arrangement can be in connection with the contact elements by means of a bond wire which interconnects respective bond wire pads on the chip with respective connecting pads on the substrate, thereby avoiding the provision of flip chips which are relatively more expensive in production. As shown with regard to the embodiments of FIGS. 1 and 2, the chip arrangements are built in the form of a BGA arrangement which is the arrangement of a chip on a BGA substrate wherein the chip may be connected with bond wires and wherein the BGA arrangement is not encapsulated with a mold such that the chip is uncovered.

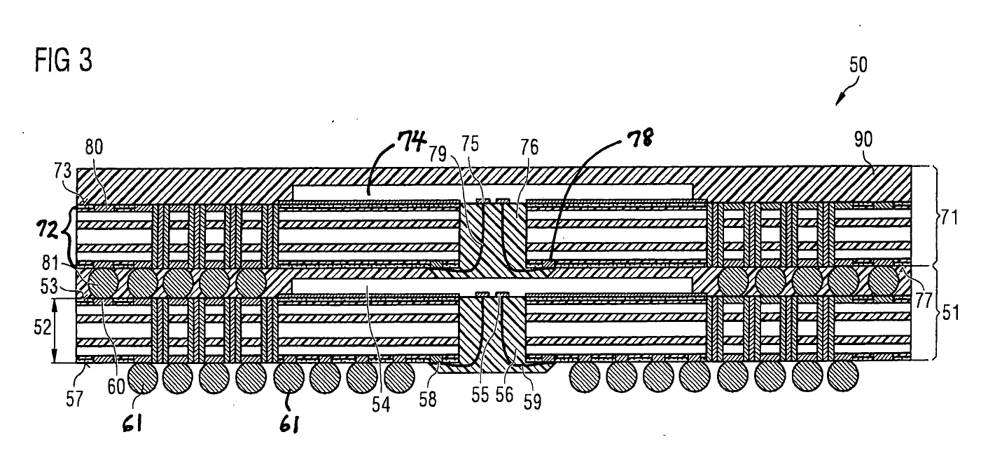

In FIG. 3, another embodiment of the present invention is shown, wherein the package substrate 11 as shown in FIGS. 1 and 2 can be omitted. The embodiment of FIG. 3 shows an integrated device 50 having two chip arrangements 51, 71 which may be equal or similar in design. A first chip arrangement 51 and a second chip arrangement 71 are stacked on each other. The first chip arrangement 51 comprises a first substrate 52 on a first surface of which a first chip 54 is placed upside-down including bonding pads 55. The first substrate 52 comprises a bonding channel 56 wherein the first chip 54 is placed on the bonding channel 56 such that the bonding pads 55 are freely accessible through the bonding channel 56 by a bonding equipment to fixate bond wires 59 on the bonding pads 55. On the second surface 57 of the first substrate 52, further bonding pads 58 are arranged close to the bonding channel 56 so that the bonding pads 55 on the first chip 54 and the further bonding pads 58 on the second surface 57 of the first substrate 52 are interconnected with bond wires 59. The further bonding pad 58 is in electrical contact with a respective first contact element 61 by means of a redistribution wiring which is provided within the first substrate 51. On the first surface 53 of the first substrate 52 on the region besides the location at which the first chip 54 is placed, further contact pads 60 are arranged. The second chip arrangement 71 has substantially a similar design as the first chip arrangement 51 with second contact elements 81, a second substrate 72, a first surface 73 of the second substrate 72, a second chip 74, bonding pads 75 of the second chip 74, a bond channel 76, a second surface 77 of the second substrate 72, further bonding pads 78 on the second surface 77, second bond wires 79 and further contact pads 80 on the first surface 73 of the second substrate 72.

In FIG. 3, the two chip arrangements 51, 71 differ in that the first chip arrangement 51 provides more first contact elements 61 than the second contact elements 81 in the second chip arrangement 71 as the first contact element 61 has to provide the electrical signaling for each of the stacked chip arrangements 51, 71 as well as thermal contact elements (heat bumps) for dissipating heat. The chip arrangements 51, 71 are stacked on each other wherein the contact elements 81 of the second chip arrangement 71 are placed on the contact pads 60 of the first chip arrangements 51 to provide an electrical interconnection.

After stacking the chip arrangements 51, 71, a common integral mold 90 is applied so that the chip arrangements 51, 71 are encapsulated in a single process step such that the second surface 57 of the first substrate 52 remains uncovered by the mold 90 such that the first contact elements 61 are freely accessible for providing electrical contacts to the first and second chips 54, 74.

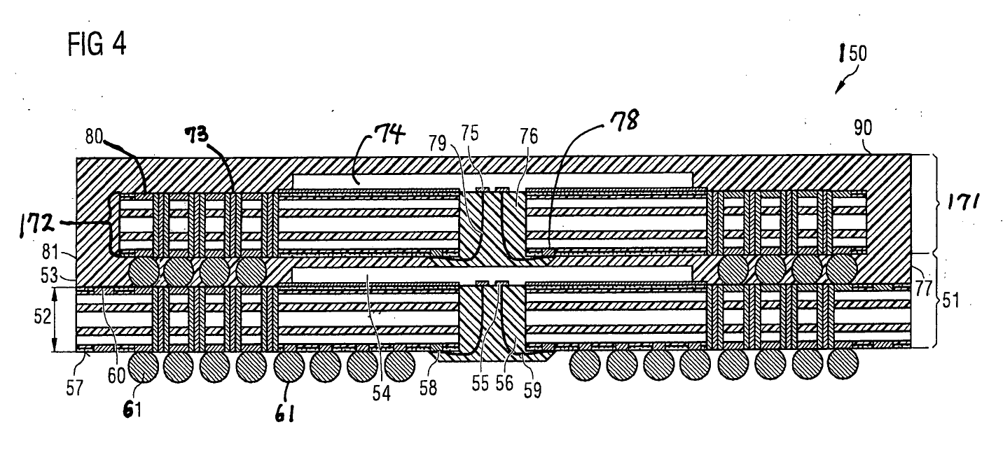

In FIG. 4, a fourth embodiment of the integrated device 151 according to the present invention is shown. Elements having the same reference signs as the elements of the embodiment of FIG. 3 have the same or similar functionality. The embodiment of FIG. 4 differs from the embodiment of FIG. 3 in that the first substrate 52 is larger in size than the second substrate 172, wherein the second chip arrangement 171 is placed on the first substrate 52 such that the second chip arrangement 171 completely lies within the area defined by the first substrate 52 of the first chip arrangement 51. The common mold 90 which is applied now encapsulates the second chip arrangement 171 and covers the first surface 53 of the first chip arrangement 51.

For any embodiments, the integrated device can be provided with one or more thermal element which, in the case of FIG. 4, can be provided as a further contact element on the second surface 57 of the first substrate 52 and which reduces the thermal resistance between the chips and a printed circuit board on which the integrated device is to be connected.

While the foregoing is directed to embodiments of the present invention, other and further embodiments of the invention may be devised without departing from the basic scope thereof, and the scope thereof is determined by the claims that follow.

What is claimed is:

1. An integrated device, comprising:
a plurality of chip arrangements which are not encapsulated individually, each chip arrangement having a plurality of contact elements for contacting a respective plurality of contact pads, wherein the plurality of chip arrangements are stacked on each other such that the contact elements provide electrical connections to the respective chip arrangement; and
a common integral mold arranged to encapsulate the plurality of stacked chip arrangements.

2. The integrated device of claim 1, wherein each chip arrangement comprises at least one of:
a flip chip on which the plurality of contact elements are directly arranged; and
a ball grid array (BGA) arrangement comprising a substrate having a first surface and a second opposing surface, wherein a chip is arranged on the first surface of the substrate and a respective plurality of contact elements is provided on the second opposing surface to provide an electrical connection with the chip.

3. The integrated device of claim 2, wherein the plurality of chip arrangements comprises at least one BGA arrangement and at least one flip chip.

4. The integrated device of claim 3, further comprising a package substrate on which the at least one BGA arrangement and the at least one flip chip is arranged.

5. The integrated device of claim 4, wherein the flip chip includes a first plurality of contact elements disposed in contact with respectively associated contact pads of the package substrate, wherein the BGA arrangement includes a second plurality of contact elements disposed in contact with respective further contact pads of the package substrate, wherein the second plurality of contact elements of the BGA arrangement are disposed outside of an area which covers the flip chip when the BGA arrangement is stacked onto the flip chip.

6. The integrated device of claim 5, wherein the common mold is disposed on one side of the package substrate.

7. The integrated device of claim 1, wherein the contact elements are formed as solder bumps.

8. A method for producing an integrated device, the method comprising:
stacking a plurality of non-encapsulated chip arrangements, each chip arrangement having a plurality of contact elements; and
encapsulating the plurality of chip arrangements with a common mold, wherein the plurality of contact elements of at least one chip arrangement is externally contactable.

9. The method of claim 8, wherein at least one of the plurality of the chip arrangements is provided as a flip chip on which the respective plurality of contact elements are directly arranged.

10. The method of claim 8, wherein at least one of the chip arrangements is provided as a ball grid array (BGA) arrangement comprising a substrate having a first surface and a second opposing surface, and wherein a chip is arranged on the first surface of the substrate and a respective plurality of contact elements is provided on the second opposing surface to provide an electrical connection with the chip.

11. The method of claim 8, wherein at least one chip arrangement is provided as a flip chip on which the respective plurality of contact elements are directly arranged and at least one chip arrangement is provided as a BGA arrangement comprising a substrate having a first surface and a second opposing surface, and wherein a chip is arranged on the first surface of the substrate and a respective further plurality of contact elements is provided on the second opposing surface to provide an electrical connection with the chip.

12. The method of claim 11, further comprising:
arranging the flip chip on a package substrate, wherein the contact elements of the flip chip are disposed in contact with respectively associated contact pads of the package substrate; and
stacking the BGA arrangement over the flip chip on the package substrate, wherein the contact elements of the BGA arrangement are disposed in contact with respective further contact pads of the package substrate, wherein the contact elements of the BGA arrangement are disposed outside of an area which covers the flip chip when the BGA arrangement is stacked onto the flip chip.

13. An integrated device, comprising:
a first chip arrangements connected to a first plurality of contact elements;
a second chip arrangements connected to a second plurality of contact elements, wherein the second chip arrangement is stacked over the first chip arrangement, to form a chip stack, wherein the first and second chip arrangements are not individually encapsulated, and wherein; and
a common integral mold disposed to encapsulate a first side of the chip stack, wherein the first and second contact elements are disposed on a non-encapsulated side the chip stack to provide electrical connections respectively to the first and second chip arrangements.

14. The integrated device of claim 13, further comprises a package substrate having a first surface and a second opposite surface, wherein the mold-encapsulated chip stack is disposed on the first surface of the package substrate and wherein the first and second contact elements are dispose on the second surface of the package substrate.

15. The integrated device of claim 14, wherein the first chip arrangement comprises a flip chip disposed on the first surface of package substrate, and wherein the second chip arrangement comprises a ball grid array (BGA) arrangement comprising a BGA substrate, a second chip disposed on the BGA substrate and a plurality of intermediate contact elements disposed in connection between the BGA substrate and the package substrate.

16. The integrated device of claim 15, wherein the plurality of intermediate contact elements are disposed in an outer area of the BGA substrate and wherein the second chip is disposed in a central area of the BGA substrate, stacked over the flip chip.

17. The integrated device of claim 16, further comprising:
a third chip arrangement disposed in a stacked arrangement over the second chip arrangement, wherein the third chip arrangement comprises a further BGA arrangement comprising a further BGA substrate, a third chip disposed on the further BGA substrate and a further plurality of intermediate contact elements disposed in connection between the further BGA substrate and the BGA substrate of the second chip arrangement.

18. The integrated device of claim 13, wherein the first chip arrangement comprises:
a first substrate having a first surface and a second opposite surface, wherein a bond channel is formed between the first surface and the second surface; and
a first chip disposed on the first surface and connected to bonding pads disposed on the first surface, wherein the first plurality of contact elements are disposed on the second surface of the first substrate, and wherein the first plurality of contact elements are electrically connected to the first chip via bonding wires connected to the bond pads.

19. The integrated device of claim 18, wherein the second chip arrangement comprises:
a second substrate having a first surface and a second opposite surface, wherein a second bond channel is formed between the first surface and the second surface of the second substrate; and
a second chip disposed on the first surface of the second substrate and connected to bonding pads disposed on the first surface of the second substrate, wherein the second plurality of contact elements are disposed on the second surface of the first substrate, wherein a plurality of intermediate contact elements electrically connected to the second chip via bonding wires connected to the second bond pads, and wherein the plurality of intermediate contact elements are disposed between the second substrate and the first substrate and electrically connected to the second plurality of contact elements through the first substrate.

20. The integrated device of claim 19, wherein the plurality of intermediate contact elements and the second plurality of contact elements are disposed in an outer area of the first substrate and wherein the first chip is disposed in a central area of the first substrate, in a stacked arrangement with the second chip.
